(19) United States
(12) Patent Application Publication
(10) Pub. No.: US 2013/0029473 A1
(43) Pub. Date: Jan. 31, 2013

(54) METHOD OF CLEAVING SUBSTRATE AND METHOD OF MANUFACTURING BONDED SUBSTRATE USING THE SAME

(71) Applicants: Dong-Woon KIM, ChungCheongNam-Do (KR); Donghyun Kim, ChungCheongNam-Do (KR); Mikyoung Kim, ChungCheongNam-Do (KR); MINJU KIM, ChungCheongNam-Do (KR); SEUNG YONG PARK, ChungCheongNam-Do (KR); Seulgi Bae, ChungCheongNam-Do (KR); JOONG WON SHUR, ChungCheongNam-Do (KR); Yulia Yu, ChungCheongNam-Do (KR); Bohyun Lee, ChungCheongNam-Do (KR); BONGHEE JANG, ChungCheongNam-Do (KR)

(72) Inventors: Dong-Woon KIM, ChungCheongNam-Do (KR); Donghyun Kim, ChungCheongNam-Do (KR); Mikyoung Kim, ChungCheongNam-Do (KR); MINJU KIM, ChungCheongNam-Do (KR); SEUNG YONG PARK, ChungCheongNam-Do (KR); Seulgi Bae, ChungCheongNam-Do (KR); JOONG WON SHUR, ChungCheongNam-Do (KR); Yulia Yu, ChungCheongNam-Do (KR); Bohyun Lee, ChungCheongNam-Do (KR); BONGHEE JANG, ChungCheongNam-Do (KR)

(73) Assignee: SAMSUNG CORNING PRECISION MATERIALS CO., LTD.

(21) Appl. No.: 13/558,932

(22) Filed: Jul. 26, 2012

(30) Foreign Application Priority Data
Jul. 26, 2011 (KR) 10-2011-0074054

(51) Int. Cl. H01L 21/304; H01L 21/265

(52) U.S. Cl. 438/458; 438/795; 257/E21.237; 257/E21.334

(57) ABSTRACT

A method of cleaving a substrate and a method of manufacturing a bonded substrate using the same, in which warping in a cleaved substrate is reduced. The method includes the following steps of: forming an ion implantation layer by implanting ions into a substrate; annealing the substrate in which the ion implantation layer is formed; implanting ions again into the ion implantation layer of the substrate; and cleaving the substrate along the ion implantation layer by heating the substrate into which ions are implanted.

### CROSS REFERENCE TO RELATED APPLICATION

The present application claims priority from Korean Patent Application Number 10-2011-0074054 filed on Jul. 26, 2011, the entire contents of which application are incorporated herein for all purposes by this reference.

### BACKGROUND OF THE INVENTION

1. Field of the Invention

The present invention relates to a method of cleaving a substrate and a method of manufacturing a bonded substrate using the same, and more particularly, to a method of cleaving a substrate and a method of manufacturing a bonded substrate using the same, in which warping in a cleaved substrate is reduced.

2. Description of Related Art

Recently, studies on compound semiconductors made of a compound of two or more elements, such as aluminum nitride (AlN), gallium nitride (GaN) or indium nitride (InN), as materials for cutting edge devices, such as light-emitting diodes (LEDs) and laser diodes (LDs), are actively underway.

In particular, since GaN has a very large transition energy bandwidth, it can generate light in the range from ultraviolet (UV) to blue rays. This feature makes GaN an essential next-generation photoelectric material that is used for blue laser diodes (LDs), which are regarded as light sources for next-generation digital versatile discs (DVDs), white light-emitting diodes (LEDs), which can replace the existing illumination devices, high-temperature and high-power electronic devices, and the like.

A semiconductor device made of such compound semiconductor is fabricated on a bonded substrate that includes a compound semiconductor substrate and a carrier substrate, which are bonded to each other, by a process such as an epitaxial process or an etching process.

Accordingly, a method of manufacturing a bonded substrate is described as an example with respect to a GaN substrate.

FIG. 1 and FIG. 2 are illustrative views depicting a method of manufacturing a bonded substrate of the related art.

Referring to FIG. 1, in the method of manufacturing a bonded substrate of the related art, first, a sapphire substrate 11 is loaded into a reactor. A mixture gas of ammonia (NH₃) and hydrogen chloride (HCl) is blown over the sapphire substrate 11 in order to perform surface treatment before a GaN substrate is grown. Afterwards, a GaN substrate 21 is grown by blowing gallium chloride (GaCl) and ammonia along with a carrier gas onto the sapphire substrate 11 in the state in which the temperature inside the reactor is maintained at a high temperature of 100° C. or higher. After that, the sapphire substrate 11 on which the GaN substrate 21 is grown is cooled for approximately 8 hours. The cooled sapphire substrate 11 on which the GaN substrate 21 is grown is etched using phosphoric acid. Afterwards, the sapphire substrate 11 on which the GaN substrate 21 is grown is transported into a laser cutting furnace, and is then irradiated with a laser beam, so that the GaN substrate 21 is separated therefrom.

After that, a bonded substrate is manufactured using the separated GaN substrate 21. Describing this process with reference to FIG. 2, an ion implantation layer 21a is formed in the GaN substrate 21 by implanting ions into the nitrogen (N) face of the GaN substrate 21 using an ion implanter. In sequence, in the state in which a carrier substrate 31 is brought into contact with the nitrogen face of the GaN substrate (21), the GaN substrate 21 and the carrier substrate 31 are bonded to each other, thereby manufacturing a bonded substrate. Afterwards, the ion implantation layer inside the GaN substrate 21 of the bonded substrate is transformed into a gas layer by applying heat, so that the bonded substrate is cleaved along the gas layer formed inside the GaN substrate 21.

The technology that implants ions into a first substrate, which is subjected to bonding, bonds the first substrate to a second substrate, i.e. the carrier substrate, and then cleaves the first substrate along the ion implantation layer as described above is referred to as layer transfer technology.

However, the technology for cleaving the substrate using the ion implantation of the related art, which is used in the layer transfer technology, has problems in that the first substrate is warped by stress due to the ion implantation and thus the quality of bonding between the first and second substrates is degraded.

In addition, since the ion implantation layer is formed wide, the layer that is damaged by the ion implantation is thickened, thereby degrading the quality of the cleaved substrate.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of cleaving a substrate, which improves the quality of cleaved substrate, and prevents the substrate from warping.

In an aspect of the present invention, provided is a method of cleaving a substrate. The method includes the following steps of: forming an ion implantation layer by implanting ions into a substrate; annealing the substrate in which the ion implantation layer is formed; implanting ions again into the ion implantation layer of the substrate; and cleaving the substrate along the ion implantation layer by heating the substrate into which ions are implanted.

In an exemplary embodiment, the step of annealing the substrate and implanting ion again may be repeated multiple times.

Here, ions that are implanted may be ions of at least one selected from among hydrogen, helium, nitrogen, oxygen and argon.

In another exemplary embodiment, the step of annealing the substrate may be carried out below a temperature at which the substrate is cleaved along the ion implantation layer.

In another aspect of the present invention, provided is a method of manufacturing a cleaved substrate. The method includes the following steps of: forming an ion implantation layer by implanting ions into a compound semiconductor substrate; annealing the substrate the compound semiconductor substrate in which the ion implantation layer is formed; implanting ions again into the ion implantation layer of the compound semiconductor substrate; preparing a bonded substrate by bonding the compound semiconductor substrate, into which ions are implanted again, to a carrier substrate; and cleaving the compound semiconductor substrate along the ion implantation layer by heating the bonded substrate.

In an exemplary embodiment, the compound semiconductor substrate may be a gallium nitride substrate.

In another exemplary embodiment, the carrier substrate may be made of one material selected from among silicon (Si), aluminum nitride (AlN), beryllium oxide (BeO), gallium arsenide (GaAs), gallium nitride (GaN), germanium (Ge), indium phosphide (InP), lithium niobate (LiNbO₃) and lithium tantalate (LiTaO₃).

The step of bonding the compound semiconductor substrate to the carrier substrate may be carried out by surface activation due to plasma treatment.

According to embodiments of the invention, there are effects of reducing warping in the cleaved substrate and improving the surface coarseness and quality of the cleaved substrate since the annealing, which relieves the substrate from stress, is subsequent to the ion implantation.

In addition, there is an effect of increasing the area where the cleaved substrate is bonded with the carrier substrate, so that a high-quality bonded substrate can be manufactured.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 and FIG. 2 are illustrative views depicting a method of manufacturing a bonded substrate of the related art;

FIG. 3 is a schematic flowchart depicting a method of cleaving a substrate according to an exemplary embodiment of the invention; and

FIG. 4 is a schematic flowchart depicting a method of manufacturing a bonded substrate according to another exemplary embodiment of the invention.

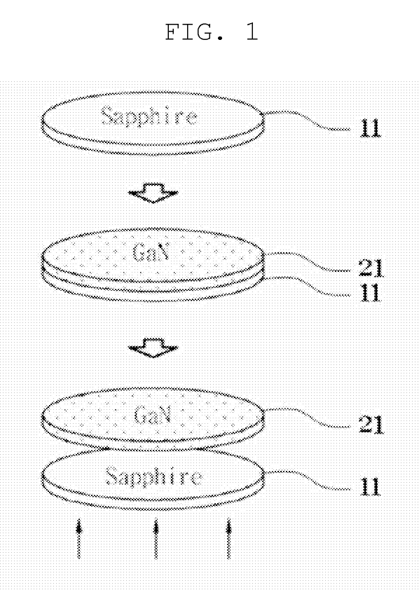

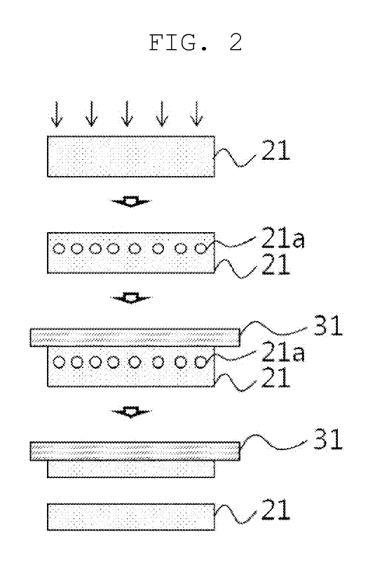

### DETAILED DESCRIPTION OF THE INVENTION

Reference will now be made in detail to a method of cleaving a substrate and a method of manufacturing a bonded substrate using the same according to the invention, embodiments of which are illustrated in the accompanying drawings and described below.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

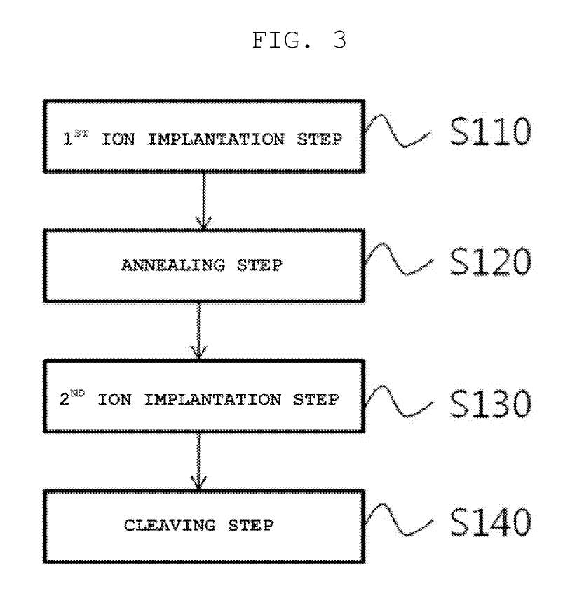

FIG. 3 is a schematic flowchart depicting a method of cleaving a substrate according to an exemplary embodiment of the invention.

Referring to FIG. 3, the method of cleaving a substrate of this embodiment includes a first ion implantation step, an annealing step, a second ion implantation step, and a cleaving step.

First, at S110, an ion implantation layer is formed in a substrate by implanting ions into the substrate in order to cleave the substrate.

Here, the substrate may be a compound semiconductor substrate that is grown from aluminum nitride (AlN), gallium nitride (GaN), indium nitride (InN) or the like by a variety of methods, such as metal organic chemical vapor deposition (MOCVD), molecular beam epitaxy (MBE), hydride vapor epitaxy (HVPE) or the like.

The ion implantation layer is formed by implanting ions into the substrate using an ion implanter.

Ions that are implanted in this step may be ions of one selected from among hydrogen, nitrogen, oxygen, argon and mixtures thereof.

The range of energy that is required for the ion implantation is determined depending on the type of ions that are implanted and the depth to which ions are implanted. The depth to which ions are implanted may be determined depending on the thickness of a substrate that is intended to be manufactured. In addition, the amount of ions that are implanted may be smaller than the amount of ions that are implanted in order to cleave a substrate in the related art.

Afterwards, at S120, the substrate in which the ion implantation layer is formed is annealed.

The annealing may be performed at a temperature at which the substrate is not cleaved along the ion implantation layer, i.e. a temperature that is below a temperature at which the substrate is cleaved. The effects of this annealing include relieving the substrate from stress that is caused by ions that are implanted in the first ion implantation step, and allowing ions that are to be implanted in the following second ion implantation step to be effectively implanted into the ion implantation layer, which is formed in the first ion implantation step.

In sequence, at S130, ions are implanted again into the ion implantation layer.

Ions that are implanted in this step may be the same as or different from ions that are implanted in the first ion implantation step.

The energy that is applied to implanted ions may be the same as the energy that is applied to ions in the first ion implantation step.

The amount of ions that are implanted in this step may be the same as or different from the amount of ions that are implanted in the first ion implantation step. Specifically, if ions that are implanted in the first ion implantation step are uniformly distributed in the ion implantation layer due to the annealing, the amount of ions that are implanted in the second ion implantation step may be smaller than the amount of ions that are implanted in the first ion implantation step.

Finally, at S140, the substrate is cleaved along the ion implantation layer by heating the substrate, thereby manufacturing a cleaved substrate.

When the substrate is heated, the ion implantation layer formed inside the substrate is converted into a gas layer, so that the substrate is cleaved into two substrate parts along the gas layer.

In addition, in the method of cleaving a substrate of this embodiment, the annealing steps and the second ion implantation steps in turn may be repeated multiple times.

Here, the amount of ions that are implanted in each ion implantation step may be obtained by dividing the amount of ions that are implanted in the related art by the number of the ion implantation steps. Alternatively, the amount of implanted ions may also be controlled based on the degree of uniformity with which implanted ions are distributed by the annealing, so that the amount of ions implanted in each ion implantation step varies.

Unlike the method of the related art in which N ions is implanted one time using a certain amount of energy X, N/M ions is implanted M times using energy X (where M is the number of ion implantation steps) and the annealing step is added between the ion implantation steps. Consequently, it is possible to increase the area where the cleaved substrate is bonded to the carrier substrate while improving the surface coarseness (roughness) and the quality of the cleaved substrate.

That is, when ions are implanted into the substrate, the substrate is warped due to stress that is caused by a change in the crystal lattice structure or the like of the substrate. According to an embodiment of the invention, ions are implanted multiple times each in a divided amount, and the annealing is performed subsequent to the ion implantation so that the substrate is relieved from stress, thereby reducing warping in the substrate. Consequently, it is possible to increase the area of the cleaved substrate that is bonded to the carrier substrate.

In addition, in the method of the related art, since N number of ions is implanted one time, a wide ion implantation layer is formed, thereby increasing the thickness of a damaged layer. In contrast, according to an embodiment of the invention, N/M number of ions is implanted multiple times, and an annealing step is added between ion implantation steps, so that implanted ions are concentrated to the ion implantation layer, which is formed by the first ion implantation step, thereby causing the ion implantation layer to be narrow and uniform. This can consequently reduce the layer that is damaged by the ion implantation. Accordingly, it is possible to improve the surface coarseness and the quality of the cleaved substrate over those of a substrate that is cleaved according to the related art.

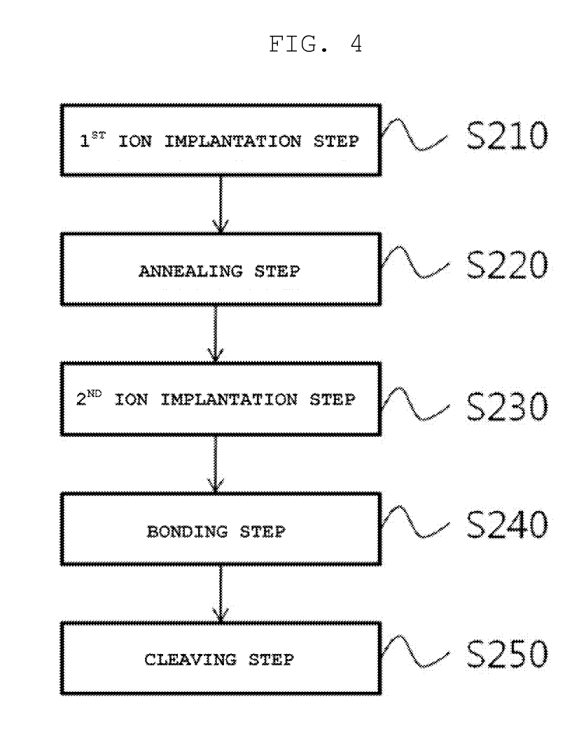

FIG. 4 is a schematic flowchart depicting a method of manufacturing a bonded substrate according to another exemplary embodiment of the invention.

Referring to FIG. 4, the method of manufacturing a bonded substrate of this embodiment includes a first ion implantation step, an annealing step, a second ion implantation step, a bonding step, and a cleaving step.

First, at S210, an ion implantation layer is formed in a compound semiconductor substrate by implanting ions into the substrate in order to manufacture the bonded substrate.

Here, the compound semiconductor substrate may be a gallium nitride (GaN) substrate, and ions implanted may be ions of one element selected from among hydrogen, nitrogen, oxygen and argon.

The energy that is required for the ion implantation may range from 10 Kev to 900 KeV, the amount of implanted ions may range from 0.5×10¹⁴ cm² to 0.5×10¹⁹ cm², and the depth to which ions are implanted may range from 0.001 μm to 10 μm.

Afterwards, at S220, the compound semiconductor substrate in which the ion implantation layer is formed is annealed.

The annealing may be performed under a temperature at which the compound semiconductor substrate is cleaved along the ion implantation layer that is formed by the first ion implantation step.

After that, at S230, ions are implanted again into the ion implantation layer. Here, the conditions under which ions are to be implanted may be the same as those of the first ion implantation step.

Afterwards, at S240, a bonded substrate is prepared by bonding the compound semiconductor substrate, which underwent the second ion implantation step, to a carrier substrate.

The carrier substrate may be made of one material selected from among silicon (Si), aluminum nitride (AlN), beryllium oxide (BeO), gallium arsenide (GaAs), gallium nitride (GaN), germanium (Ge), indium phosphide (InP), lithium niobate and lithium tantalite.

The bonding between the compound semiconductor substrate and the carrier substrate may be performed by surface activation in which a bonding surface is activated by exposing it to plasma and is then bonded at a low temperature ranging from room temperature to 400° C. Alternatively, the bonding surface may be bonded by applying heat and pressure thereto. In an example, the bonding between the compound semiconductor substrate and the carrier substrate may be performed under the conditions in which the temperature ranges from 20° C. to 500° C. and the heat treatment time ranges from 1 to 600 minutes.

Finally, at S250, the compound semiconductor substrate is cleaved into two substrates along the ion implantation layer by heating the compound semiconductor substrate, thereby manufacturing a bonded substrate in which one part of the compound semiconductor substrate is bonded to the carrier substrate.

The bonded substrate, which is manufactured in this fashion, will be used in a substrate for LED devices or in another type of semiconductor substrate.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of cleaving a substrate, comprising:
a first ion implantation step of forming an ion implantation layer by implanting ions into the substrate;
an annealing step of annealing the substrate;
a second ion implantation step of implanting ions again into the ion implantation layer of the substrate; and
a cleaving step of cleaving the substrate along the ion implantation layer by heating the substrate.

2. The method of claim 1, wherein the annealing step and the second ion implantation step in turn are repeated multiple times.

3. The method of claim 1, wherein the ions implanted in the first ion implantation step and the ions implanted in the second ion implantation step are ions of at least one selected from the group consisting of hydrogen, helium, nitrogen, oxygen and argon.

4. The method of claim 1, wherein the annealing step is carried out below a temperature at which the substrate is cleaved along ion implantation layer.

5. A method of manufacturing a cleaved substrate, comprising:
forming an ion implantation layer by implanting ions into a compound semiconductor substrate;
annealing the compound semiconductor substrate;
implanting ions again into the ion implantation layer of the compound semiconductor substrate;
preparing a bonded substrate by bonding the compound semiconductor substrate to a carrier substrate; and
cleaving the compound semiconductor substrate along the ion implantation layer by heating the bonded substrate.

6. The method of claim 5, wherein the compound semiconductor substrate is a gallium nitride substrate.

7. The method of claim 5, wherein the carrier substrate is made of one material selected from the group consisting of silicon, aluminum nitride, beryllium oxide, gallium arsenide, gallium nitride, germanium, indium phosphide, lithium niobate and lithium tantalite.

8. The method of claim 5, wherein bonding the compound semiconductor substrate to the carrier substrate is carried out using a plasma activated bonding.
